(19) United States
(12) Patent Application Publication
(10) Pub. No.: US 2009/0184304 A1
(43) Pub. Date: Jul. 23, 2009

(54) PHASE CHANGE MEMORY DEVICE HAVING PLUG-SHAPED PHASE CHANGE LAYERS AND METHOD FOR MANUFACTURING THE SAME

(76) Inventors: Heon Yong CHANG, Gyeonggi-do (KR); Suk Kyoung HONG, Gyeonggi-do (KR)

Correspondence Address: LADAS & PARRY LLP, 224 SOUTH MICHIGAN AVENUE, SUITE 1600, CHICAGO, IL, 60604, US

(21) Appl. No.: 12/044,047

(22) Filed: Mar. 7, 2008

(30) Foreign Application Priority Data
Jan. 18, 2008 (KR) 10-2008-0005899

(51) Int. Cl. H01L 45/00

(52) U.S. Cl. 257/2; 438/54; 257/E45.002

(57) ABSTRACT

A phase change memory device having plug-shaped phase change layers and a process of manufacturing the same is provided. The device and process includes forming first electrodes on a substrate. An insulation layer is then formed to cover the first electrodes. Plug-shaped phase change layers are then formed in the insulation layer to contact the first electrodes. The plug-shaped phase change layers have a straight-line or an ‘L’ shape when viewed as a cross-section and a horseshoe or a semicircle shape when viewed from above. Finally, bit lines are formed on the insulation layer to contact the phase change layers and additionally serve as second electrodes. The device may further include heaters interposed between the first electrodes and the plug-shaped phase change layers.

### CROSS-REFERENCE TO RELATED APPLICATIONS

The present application claims priority to Korean patent application number 10-2008-0005899 filed on Jan. 18, 2008, which is incorporated herein by reference in its entirety.

### BACKGROUND OF THE INVENTION

The present invention relates to a phase change memory device and a method for manufacturing the same, and more particularly, to a phase change memory device which can prevent the etch loss of a phase change material layer and can decrease programming current and a method for manufacturing the same.

In general, memory devices are largely divided into two types, volatile RAM (random access memory) which loses inputted information when power is interrupted and non-volatile ROM (read-only memory) which can continuously maintain the stored state of inputted information even when power is interrupted. Volatile RAM may include DRAM (dynamic RAM) and SRAM (static RAM). Non-volatile ROM may include a flash memory device such as an EEPROM (electrically erasable and programmable ROM).

As is well known in the art, although DRAM is an excellent memory device, DRAM requires a high charge storing capacity, and therefore, it is difficult to obtain a high level of integration because the surface area of an electrode must be increased accordingly. Further, in a flash memory device, a high operation voltage is required when compared to a power source voltage due to the fact that two gates are stacked upon each other, and thus it is difficult to obtain a high level of integration because a separate booster circuit is needed in order to supply the voltage required for write and delete operations.

As a result, research were carried out in an effort to develop a novel memory device having a simple configuration capable of obtaining a high level of integration while retaining the characteristics of non-volatile memory device. For example, a phase change memory device has recently been proposed.

In a phase change memory device, a phase change occurs in a phase change layer interposed between a lower electrode and an upper electrode from a crystalline state to an amorphous state due to current flow between the lower electrode and the upper electrode. Information stored in a cell is recognized by using a difference in resistance between the crystalline state and the amorphous state.

Specifically, in the phase change memory device, a chalcogenide layer being a compound layer made of germanium (Ge), stibium (Sb) and tellurium (Te) is used as a phase change layer. As current is applied, the phase change layer undergoes a phase change via heat, i.e., Joule heat, between the amorphous state and the crystalline state. Accordingly, in the phase change memory device, the specific resistance of the phase change layer in the amorphous state is higher than the specific resistance of the phase change layer in the crystalline state. Based on this fact, in a read mode, by sensing the current flowing through the phase change layer, it is determined whether the information stored in a phase change cell has a logic value of ‘1’ or ‘0’.

A phase change cell of the phase change memory device is formed such that, after forming a lower electrode, a phase change material layer and an upper electrode material are sequentially deposited on the lower electrode and are then continuously etched so that an upper electrode and a phase change layer are formed.

However, according to this conventional method of forming a phase change cell, an etch loss may be caused because the periphery of the phase change material layer is exposed, and thereby, the initial composition of the phase change material layer is likely to be changed. In particular, if the initial composition of the phase change material layer is changed, a sensing margin is deteriorated because the distribution of programming current required for a phase change over the entire region of a semiconductor substrate is enlarged which is a problem. Also, although not described above, it is customary to implement a cleaning process after forming the phase change layer by etching the phase change material layer. In the course of implementing the cleaning process, lifting of the phase change layer is likely to occur, by which the characteristics of the interface between the lower electrode and the phase change layer can be degraded. As a result, the endurance of the phase change memory device can be degraded as the current needed for changing the phase of the phase change layer to an amorphous state increases. In addition, after etching the upper electrode material and the phase change material layer, the periphery of the upper electrode that is exposed to the outside must be covered by a passivation layer. Incidentally, as the size of a cell and the pitch between cells decrease, voids can be generated. Further, in order to decrease a programming current, it is necessary to decrease the contact area between an electrode or a heater and the phase change layer. However, due to the limitations of a photolithographic process, it is difficult to decrease this contact area.

### SUMMARY OF THE INVENTION

Embodiments of the present invention are directed to a phase change memory device which can prevent the composition of a phase change material layer from being changed, and a method for manufacturing the same.

Embodiments of the present invention are also directed to a phase change memory device which can decrease a cell size and can standardize the distribution of programming current, and a method for manufacturing the same.

In addition, embodiments of the present invention are directed to a phase change memory device which can prevent voids from being generated and the endurance of the phase change memory device from being deteriorated, and a method for manufacturing the same.

Moreover, embodiments of the present invention are directed to a phase change memory device which can further decrease a programming current by overcoming the limitations of a photolithographic process, and a method for manufacturing the same.

In one aspect, a phase change memory device comprises first electrodes; an insulation layer formed to cover the first electrodes; plug-shaped phase change layers formed in the insulation layer to come into contact with the first electrodes; and bit lines formed on the insulation layer to come into contact with the phase change layers and serving as second electrodes.

The plug-shaped phase change layers have the sectional shape of a straight line or an ‘L’ when viewed from the side.

The plug-shaped phase change layers have the sectional shape of a horseshoe or a semicircle when viewed from the top.

The phase change memory device further comprises heaters formed from a conductive layer and interposed between the first electrodes and the plug-shaped phase change layers.

Both the heaters and the plug-shaped phase change layers have the sectional shape of a straight line when viewed from the cross section, or the heaters have the sectional shape of an ‘L’ and the plug-shaped phase change layers have the sectional shape of a straight line when viewed from the cross section.

In another aspect, a phase change memory device comprises a semiconductor substrate having switching elements; a first insulation layer formed on the semiconductor substrate; first electrodes formed in the first insulation layer; plug-shaped phase change layers formed to come into contact with the first electrodes; a second insulation layer formed on portions of the first electrodes and one portion of the first insulation layer, which is adjacent to the portions of the first electrodes, to come into contact with first surfaces of the phase change layers; a third insulation layer formed on remaining portions of the first electrodes and the other portion of the first insulation layer, which is adjacent to the remaining portions of the first electrodes, to come into contact with second surfaces of the phase change layers; and bit lines formed on the second insulation layer and the third insulation layer to come into contact with the phase change layers, and serving as second electrodes.

Each of the first insulation layer, the second insulation layer and the third insulation layer can be an oxide layer.

The phase change memory device further comprises a fourth insulation layer formed on the second insulation layer to be interposed between the second insulation layer and the bit lines, and the fourth insulation layer can be a nitride layer.

The plug-shaped phase change layers have the sectional shape of a straight line when viewed from the cross section.

The plug-shaped phase change layers have the sectional shape of an ‘L’ when viewed from the cross section. Preferably, in two adjoining cells, the plug-shaped phase change layers have the sectional shapes of an ‘L’ and a mirror-imaged ‘L’ when viewed from the cross section.

The plug-shaped phase change layers have the sectional shape of a horseshoe when viewed from the top. Preferably, in two adjoining cells, the plug-shaped phase change layers have the sectional shapes of horseshoes which are respectively open rightward and leftward when viewed from the top.

The plug-shaped phase change layers have the sectional shape of a semicircle when viewed from the top. Preferably, in two adjoining cells, the plug-shaped phase change layers have the sectional shapes of semicircles which are respectively open rightward and leftward when viewed from the top.

The phase change memory device further comprises heaters formed from a conductive layer and interposed between the first electrodes and the plug-shaped phase change layers.

Both the heaters and the plug-shaped phase change layers have the sectional shape of a straight line when viewed from the cross section.

The heaters have the sectional shape of an ‘L’ and the plug-shaped phase change layers have the sectional shape of a straight line when viewed from the cross section.

In another aspect, a method for manufacturing a phase change memory device comprises the steps of forming a first insulation layer on a semiconductor substrate having switching elements; forming first electrodes in the first insulation layer; forming a second insulation layer on the first insulation layer to cover the first electrodes; etching the second insulation layer and thereby defining a hole to expose portions of the first electrodes and a portion of the first insulation layer, which is placed between the exposed portions of the first electrodes, in two adjoining cells; forming a phase change material layer on the first electrodes and the first insulation layer which are exposed and on sidewalls and an upper surface of the second insulation layer which is etched; removing a portion of the phase change material layer which is formed on the first insulation layer; forming a third insulation layer on the phase change material layer to fill the hole; removing the third insulation layer and the phase change material layer to expose the second insulation layer and thereby forming plug-shaped phase change layers on both sidewalls of the hole; and forming bit lines on the second insulation layer and the third insulation layer to come into contact with the phase change layers and serve as second electrodes.

Each of the first insulation layer, the second insulation layer and the third insulation layer can be an oxide layer.

The hole is defined to have a rectangular sectional shape or an oval sectional shape when viewed from the top.

The hole is defined to expose each of the first electrodes 5˜100 nm in a width.

The plug-shaped phase change layers are formed have the sectional shape of a straight line when viewed from the cross section.

The plug-shaped phase change layers are formed to have the sectional shape of an ‘L’ when viewed from the cross section. Preferably, in two adjoining cells, the plug-shaped phase change layers are formed to have the sectional shapes of an ‘L’ and a mirror-imaged ‘L’ when viewed from the cross section.

The plug-shaped phase change layers are formed to have the sectional shape of a horseshoe when viewed from the top. Preferably, in two adjoining cells, the plug-shaped phase change layers are formed to have the sectional shapes of horseshoes which are respectively open rightward and leftward when viewed from the top.

The plug-shaped phase change layers are formed to have the sectional shape of a semicircle when viewed from the top. Preferably, in two adjoining cells, the plug-shaped phase change layers are formed to have the sectional shapes of semicircles which are respectively open rightward and leftward when viewed from the top.

In another aspect, a method for manufacturing a phase change memory device comprises the steps of forming a first insulation layer on a semiconductor substrate having switching elements; forming first electrodes in the first insulation layer; forming a second insulation layer on the first insulation layer to cover the first electrodes; forming a fourth insulation layer on the second insulation layer; etching the fourth insulation layer and the second insulation layer and thereby defining a hole to expose portions of the first electrodes and a portion of the first insulation layer, which is placed between the exposed portions of the first electrodes, in two adjoining cells; forming a phase change material layer on the first electrodes and the first insulation layer which are exposed, on sidewalls of the fourth insulation layer and the second insulation layer which are etched, and on an upper surface of the fourth insulation layer; removing a portion of the phase change material layer which is formed on the first insulation layer; forming a third insulation layer on the phase change material layer to fill the hole; removing the third insulation layer and the phase change material layer to expose the fourth insulation layer and thereby forming plug-shaped phase change layers on both sidewalls of the hole; and forming bit lines on the fourth insulation layer and the third insulation layer to come into contact with the phase change layers and serve as second electrodes.

The first insulation layer, the second insulation layer and the third insulation layer can be oxide layers, and the fourth insulation can be a nitride layer.

In still another aspect, a method for manufacturing a phase change memory device comprises the steps of forming a first insulation layer on a semiconductor substrate having switching elements; forming first electrodes in the first insulation layer; forming a second insulation layer on the first insulation layer to cover the first electrodes; etching the second insulation layer and thereby defining a hole to expose portions of the first electrodes and a portion of the first insulation layer, which is placed between the exposed portions of the first electrodes, in two adjoining cells; forming a conductive layer on the portions of the first electrodes and the portion of the first insulation layer, which are exposed, and on sidewalls and an upper surface of the second insulation layer which is etched; removing a portion of the conductive layer which is formed on the first insulation layer; forming a third insulation layer on the conductive layer to fill the hole; removing the third insulation layer and the conductive layer to expose the second insulation layer and thereby forming heaters on both sidewalls of the hole; removing portions of the heaters; filling a phase change material layer in spaces defined by removal of the portions of the heaters and thereby forming plug-shaped phase change layers; and forming bit lines on the second insulation layer and the third insulation layer to come into contact with the phase change layers and serve as second electrodes.

Each of the first insulation layer, the second insulation layer and the third insulation layer can be an oxide layer.

The hole is defined to have a rectangular sectional shape or an oval sectional shape when viewed from the top.

The hole is defined to expose each of the first electrodes 5˜100 nm in a width.

The conductive layer can be made of any one selected form the group consisting of TiW, TiN and TiAlN.

The conductive layer is formed to have a thickness of 5˜50 Å.

The heaters are formed have the sectional shape of a straight line when viewed from the cross section.

The heaters are formed to have the sectional shape of an ‘L’ when viewed from the cross section. Preferably, in two adjoining cells, the heaters are formed to have the sectional shapes of an ‘L’ and a mirror-imaged ‘L’ when viewed from the cross section.

The heaters are formed to have the sectional shape of a horseshoe when viewed from the top. Preferably, in two adjoining cells, the heaters are formed to have the sectional shapes of horseshoes that are respectively open rightward and leftward when viewed from the top.

The heaters are formed to have the sectional shape of a semicircle when viewed from the top. Preferably, in two adjoining cells, the heaters are formed to have the sectional shapes of semicircles that are respectively open rightward and leftward when viewed from the top.

The step of removing portions of the heaters are implemented to a depth of 100˜2,000 Å from a surface of the second insulation layer.

The plug-shaped phase change layers are formed to have the sectional shape of a straight line when viewed from the cross section.

The plug-shaped phase change layers are formed to have the sectional shape of a horseshoe when viewed from the top. Preferably, in two adjoining cells, the plug-shaped phase change layers are formed to have the sectional shapes of horseshoes which are respectively open rightward and leftward when viewed from the top.

The plug-shaped phase change layers are formed to have the sectional shape of a semicircle when viewed from the top. Preferably, in two adjoining cells, the plug-shaped phase change layers are formed to have the sectional shapes of semicircles which are respectively open rightward and leftward when viewed from the top.

In a still further aspect, a method for manufacturing a phase change memory device comprises the steps of forming a first insulation layer on a semiconductor substrate having switching elements; forming first electrodes in the first insulation layer; forming a second insulation layer on the first insulation layer to cover the first electrodes; forming a fourth insulation layer on the second insulation layer; etching the fourth insulation layer and the second insulation layer and thereby defining a hole to expose portions of the first electrodes and a portion of the first insulation layer, which is placed between the exposed portions of the first electrodes, in two adjoining cells; forming a conductive layer on the portions of the first electrodes and the portion of the first insulation layer, which are exposed, on sidewalls of the fourth insulation layer and the second insulation layer which are etched, and on an upper surface of the fourth insulation layer; removing a portion of the conductive layer which is formed on the first insulation layer; forming a third insulation layer on the conductive layer to fill the hole; removing the third insulation layer and the conductive layer to expose the fourth insulation layer and thereby forming heaters on both sidewalls of the hole; removing portions of the heaters; filling a phase change material layer in spaces defined by removal of the portions of the heaters and thereby forming plug-shaped phase change layers; and forming bit lines on the fourth insulation layer and the third insulation layer to come into contact with the phase change layers and serve as second electrodes.

The first insulation layer, the second insulation layer and the third insulation layer can be oxide layers, and the fourth insulation can be a nitride layer.

### BRIEF DESCRIPTION OF THE DRAWINGS

FIG. 1 is a cross-sectional view illustrating a phase change memory device in accordance with a first embodiment of the present invention.

FIGS. 2A and 2B are plan views for illustrating a phase change layer in the phase change memory device in accordance with the first embodiment of the present invention.

FIGS. 3A through 3F are cross-sectional views illustrating the processes for a method of manufacturing the phase change memory device in accordance with the first embodiment of the present invention.

FIGS. 4A and 4B are plan views corresponding to FIG. 3B.

FIGS. 5A through 5C are cross-sectional views illustrating a phase change memory device in accordance with a second embodiment of the present invention and the processes for a method of manufacturing the same.

FIGS. 6A through 6C are cross-sectional views illustrating a phase change memory device in accordance with a third embodiment of the present invention and the processes for a method of manufacturing the same.

FIG. 7 is a cross-sectional view illustrating a phase change memory device in accordance with a fourth embodiment of the present invention.

FIGS. 8A through 8D are cross-sectional views illustrating a phase change memory device in accordance with a fifth embodiment of the present invention and the processes for a method of manufacturing the same.

FIG. 9 is a cross-sectional view illustrating a phase change memory device in accordance with a sixth embodiment of the present invention.

FIG. 10 is a cross-sectional view illustrating a phase change memory device in accordance with a seventh embodiment of the present invention.

FIG. 11 is a cross-sectional view illustrating a phase change memory device in accordance with an eighth embodiment of the present invention.

### DESCRIPTION OF SPECIFIC EMBODIMENTS

Hereafter, the specific embodiments of the present invention will be described in detail with reference to the attached drawings.

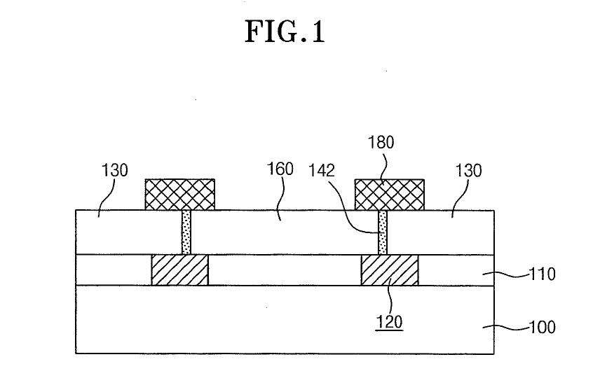

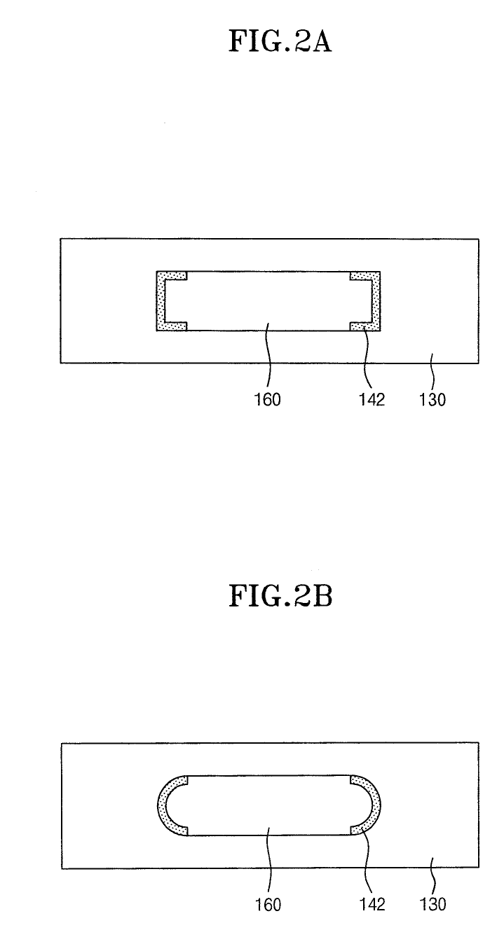

FIG. 1 is a cross-sectional view illustrating a phase change memory device in accordance with a first embodiment of the present invention. FIGS. 2A and 2B are plan views illustrating a phase change layer in the phase change memory device in accordance with the first embodiment of the present invention.

Referring to FIG. 1, a first insulation layer 110 is formed on a semiconductor substrate 100 which includes switching elements (not shown) such as transistors or diodes. First electrodes 120, which correspond to the lower electrodes of capacitors, are formed in the first insulation layer 110. The first insulation layer 110 is preferably formed of an oxide layer. Phase change layers 142 are formed in the shape of plugs on the first electrodes 120. The plug-shaped phase change layers 142 are formed on portions of the first electrodes 120 and when viewed as a cross-section have a straight-line shape.

Also, as shown in FIGS. 2A and 2B, the plug-shaped phase change layers 142 when viewed as a cross-section from above have a shape of a horseshoe or a semicircle. Preferably, when viewed from the top, the plug-shaped phase change layers 142 of two adjoining cells have the shape of horseshoes which are opened inwardly towards one another or the shape of semicircles that are opened inwardly towards one another.

Referring to FIG. 1, a second insulation layer 130 is formed on a portion of the first insulation layer 110 including portions of the first electrodes 120 so as to contact a first surface of the plug-shaped phase change layers 142. A third insulation layer 160 is formed on a remaining portion of the first insulation layer 110 including remaining portions of the first electrodes 120 so as to contact a second surface of the plug-shaped phase change layers 142. Preferably, the second insulation layer 130 and the third insulation layer 160 are oxide layers. Preferably, the second insulation layer 130 is formed on the first insulation layer 110 to contact a first surface of the first electrodes 120 which face away from each other in the two adjoining cells. That is, the second insulation layer 130 is formed to surround the first electrodes 120 and an area bound between the first electrodes 120. The third insulation layer 160 is formed on the portion of the first insulation layer 110 between the two adjoining cells to contact the second surfaces of the first electrodes 120 which face each other. That is, the third insulation layer 160 is formed within the area bounded by the first electrodes 120 and the surrounding second insulation layer 130.

Bit lines 180 are formed on the second insulation layer 130 and the third insulation layer 160 to contact the plug-shaped phase change layers 142. The bit lines 180 not only perform their native functions, that is, as data input and output lines, but also serve as second electrodes that correspond to the upper electrodes of capacitors where the bit lines 180 contact the phase change layers 142.

In the phase change memory device according to an embodiment of the present invention as configured and described above, the size of a cell can be decreased due to the phase change layer being formed in the shape of a plug and the programming current required for a phase change can be decreased due to the heat generated from a reduced height of the phase change layer.

Also, in the phase change memory device according to an embodiment of the present invention, the composition of a phase change material layer is not changed due to an etch loss on the periphery of the phase change material layer since the phase change layer is formed in the shape of a plug. Therefore, the distribution of programming current over the entire region of a semiconductor substrate can be standardized.

In the phase change memory device according to an embodiment of the present invention, a voltage drop due to a resistant component interposed between the bit line and the phase change layer can be avoided because the bit line is formed to directly contact the phase change layer. As a result, current flow can be promoted because a difference in voltage between the bit line and the first electrode can be increased.

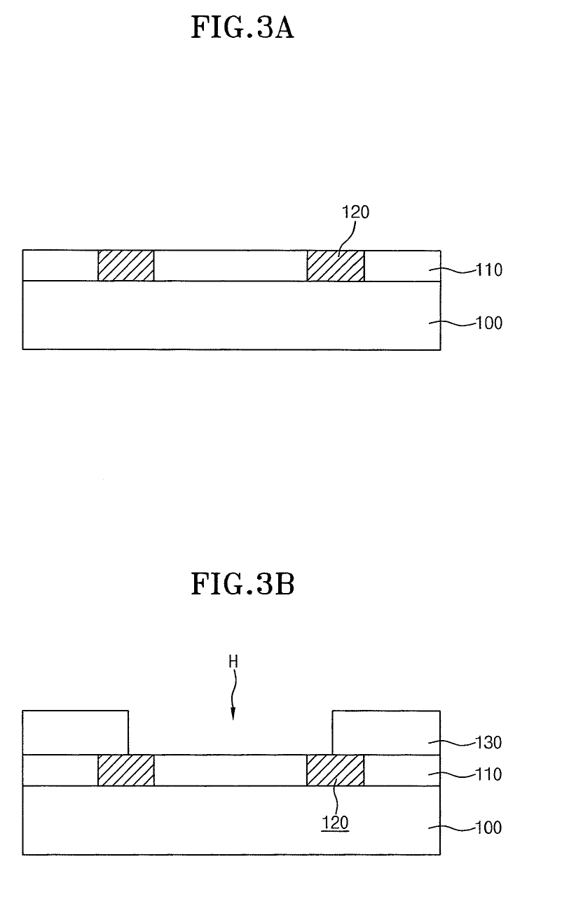

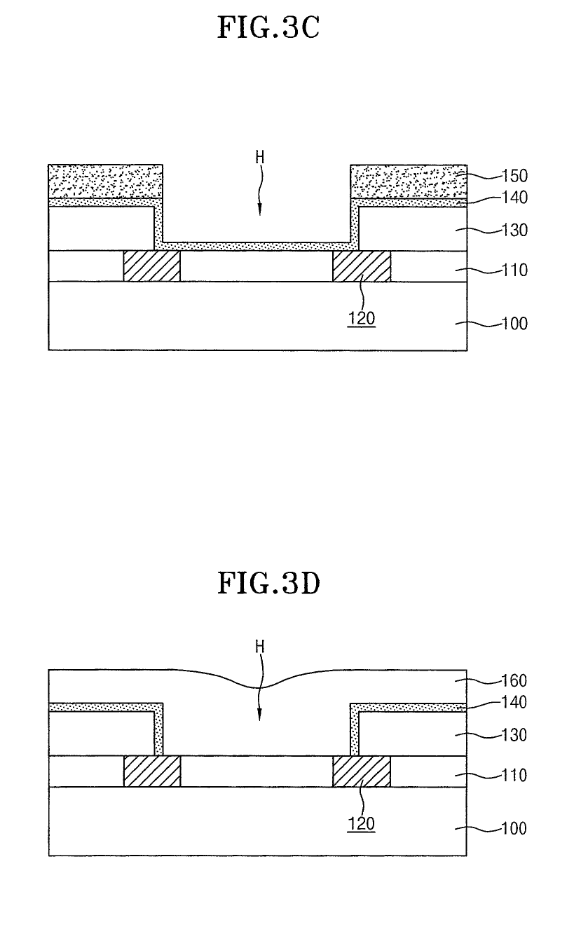

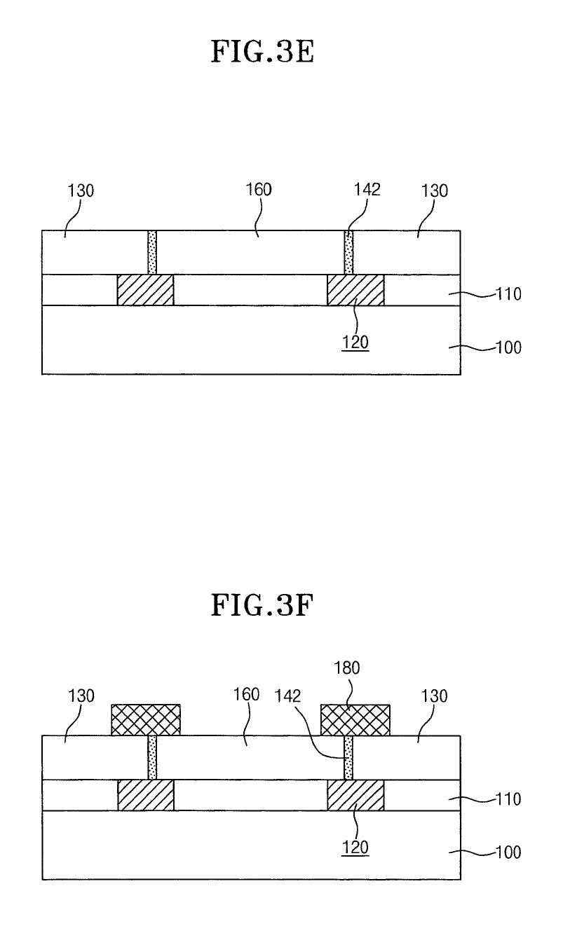

Hereinbelow, a method of manufacturing the phase change memory device in accordance with the first embodiment of the present invention will be described with reference to FIGS. 3A through 3F.

Referring to FIG. 3A, a first insulation layer 110 (e.g. an oxide layer) is formed on a semiconductor substrate 100 that has switching elements (not shown) such as transistors or diodes. The first insulation layer 110 is etched through a damascene process that is well known in the art. An electrode material is then deposited to fill the etched portions of the first insulation layer 110. First electrodes 120 are formed in the first insulation layer 110 by CMPing (chemically and mechanically polishing) the electrode material.

Referring to FIG. 3B, a second insulation layer 130 (i.e. an oxide layer) is formed on the first insulation layer 110 including the first electrodes 120. A hole H is defined in two adjoining cells to expose portions of the first electrodes 120 and a portion of the first insulation layer 110 by etching the second insulation layer 130. Preferably, the hole H is etched to expose a 5˜100 nm wide portion of each of the first electrodes 120.

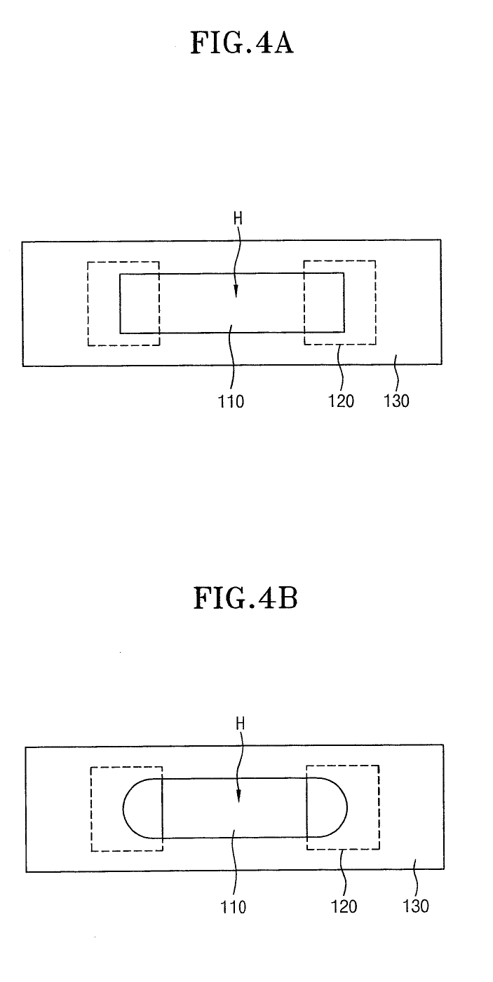

As shown in FIGS. 4A and 4B, the hole H is defined to have a rectangular shape or an oval shape when viewed from above. Specifically, the reason why the hole H is defined as an oval shape is to prevent the contact area between electrodes and phase change layers from increasing because as the contact area is increased, programming current is raised when the hole H is defined to have a circular shape.

Referring to FIG. 3C, a phase change material layer 140 is formed on the portions of the first electrodes 120 and the portion of the first insulation layer 110, which are exposed through the hole H and on the sidewalls and upper surface of the etched second insulation layer 130. Thereupon, a photoresist pattern 150 is formed on the phase change material layer 140 through a photolithographic process well known in the art. The photoresist pattern 150 is formed such that the portion of the phase change material layer 140, which is formed on the first insulation layer 110 is exposed. Specifically, the photoresist pattern 150 is formed such that a portion of the phase change material layer 140, which is formed on both the first insulation layer 110 and adjoining portions of the first electrodes 120 is exposed.

Referring to FIG. 3D, the photoresist pattern 150 is removed after etching the exposed portion of the phase change material layer 140 using the photoresist pattern 150 as an etch mask. Subsequently, a third insulation layer 160 is formed on the remaining portion of the phase change material layer 140, the exposed first insulation layer 110, and the portions of the first electrodes 120 exposed due to etching of the phase change material layer 140. The hole H is consequently filled with the third insulation layer 160.

Referring to FIG. 3E, the third insulation layer 160 and the phase change material layer 140 are CMPed (chemically and mechanically polished) until the second insulation layer 130 is exposed. Through this, plug-shaped phase change layers 142 are formed. At this time, the plug-shaped phase change layers 142 are formed on portions of the first electrodes 120 and when viewed as a cross-section have a straight-line shape.

In the phase change memory device according to an embodiment of the present invention, the size of a cell can be decreased making it possible to obtain a high level of integration of the phase change memory device due to the fact that the phase change layers 142 are formed to have the shape of a plug. In particular, the phase change layers 142 of the present invention are formed by etching only the phase change material layer 140 as compared to the conventional art in which the phase change layers are formed through continuously etching a metal layer for upper electrodes and a phase change material layer. Accordingly, in an embodiment of the present invention, an etch loss does not occur at the periphery of each phase change layer 142, and therefore, the composition of the phase change material layer 140 is not changed. As a result, in the phase change memory device according to embodiment of the present invention, the distribution of programming current over the entire region of the semiconductor substrate can be standardized.

Referring to FIG. 3F, a metal layer is deposited on the second insulation layer 130, the third insulation layer 160, and the exposed portion of the plug-shaped phase change layers 142. Then, by patterning the metal layer, bit lines 180 are formed on the second insulation layer 130 and the third insulation layer 160 such that the bit lines 180 contact the phase change layers 142. As described, the bit lines 180 not only perform their native functions, i.e., as data input and output lines, but also serve as second electrodes that correspond to the upper electrodes of capacitors where the bit lines 180 contact the phase change layers 142.

In the phase change memory device according to an embodiment of the present invention, a voltage drop due to the presence of resistant components interposed between bit lines and phase change layers does not occur because the bit lines 180 directly contact the phase change layers 142 as compared to a conventional phase change memory device. As a result, current flow can be promoted because a difference in voltage between the bit lines 180 and the first electrodes 120 can be increased.

Thereafter, while not shown in the drawings, by sequentially implementing a series of well-known subsequent processes, the manufacture of the phase change memory device in accordance with the first embodiment of the present invention is completed.

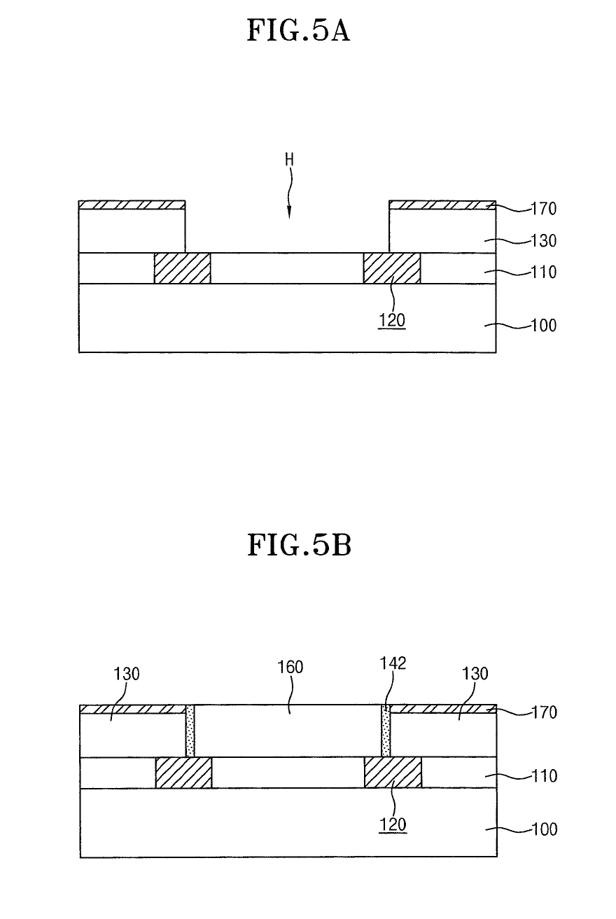

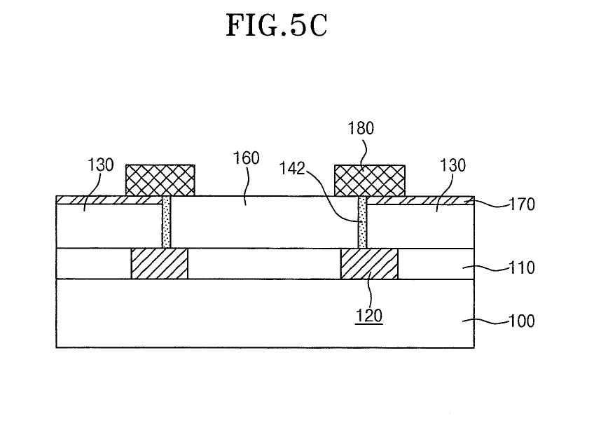

FIGS. 5A through 5C are cross-sectional views illustrating a phase change memory device in accordance with a second embodiment of the present invention and the processes for a method of manufacturing the same. Herein, the same reference numerals will be used to refer to the same parts as those shown in FIGS. 3A through 3F.

A phase change memory device in accordance with a second embodiment of the present invention has a configuration in which a fourth insulation layer 170 (i.e. a nitride layer) is further formed on the second insulation layer 130 interposed between the second insulation layer 130 and bit lines 180. Hereinbelow, a method of manufacturing this phase change memory device will be described.

Referring to FIG. 5A, a second insulation layer 130 (i.e. an oxide layer) is formed on a semiconductor substrate 100 having a first insulation layer 110 and first electrodes 120 formed thereon. A fourth insulation layer 170 (i.e. a nitride layer) is formed on the second insulation layer 130. A hole H is defined in two adjoining cells to expose portions of the first electrodes 120 and a portion of the first insulation layer 110 by etching the fourth insulation layer 170 and the second insulation layer 130. Preferably, the hole H is etched to expose a 5˜100 nm wide portion of each of the first electrodes 120. The hole H is also defined to have a rectangular shape or an oval shape when viewed from above.

In this second embodiment of the present invention, it is possible to define the hole H having a more precise sidewall profile allowing subsequent processes to be reliably implemented since the etching process for defining the hole H is implemented where the fourth insulation layer 170 (i.e. a nitride layer) is formed on the second insulation layer 130 (i.e. an oxide layer) as compared to the aforementioned first embodiment in which the hole H is defined by etching only the second insulation layer 130 (i.e. an oxide layer).

Referring to FIG. 5B, a phase change material layer 140 is formed on portions of the first electrodes 120 and a portion of the first insulation layer 110, which are exposed through the hole H, on the sidewalls of the etched second insulation layer 130 and fourth insulation layer 170, and on the upper surface of the fourth insulation layer 170. A photoresist pattern (not shown) is formed to expose a portion of the phase change material layer 140, which is formed on the first insulation layer 110 and adjoining portions of the first electrodes 120. The exposed portion of the phase change material layer 140 is etched using the photoresist pattern as an etch mask and subsequently removing the photoresist pattern.

A third insulation layer 160 is then formed on the remaining portion of the phase change material layer 140 and on the portion of the first insulation layer 110 and portions of the first electrodes 120, which are exposed due to the etching of the phase change material layer 140. The third insulation layer 160 is formed such that the hole H is filled with the third insulation layer 160. Plug-shaped phase change layers 142 that contact the first electrodes 120 are formed by CMPing the third insulation layer 160 and the phase change material layer 140 until the fourth insulation layer 170 is exposed. The plug-shaped phase change layers 142 are formed to have a straight-line shape when viewed as a cross-section and a horseshoe or semicircle shape when viewed from above. Preferably, when viewed from the top, the plug-shaped phase change layers 142 of two adjoining cells have the shape of horseshoes which are opened inwardly towards one another or the shape of semicircles which are opened inwardly towards one another.

Referring to FIG. 5C, a metal layer is deposited on the fourth insulation layer 170 and the third insulation layer 160, including the plug-shaped phase change layers 142. Bit lines 180 are formed on the fourth insulation layer 170 and the third insulation layer 160 by patterning the metal layer such that the bit lines 180 contact the phase change layers 142 and serve as second electrodes which correspond to the upper electrodes of capacitors.

In the phase change memory device according to the second embodiment of the present invention, the same effects as those of the aforementioned first embodiment are obtained, and therefore, a detailed description thereof will be omitted herein.

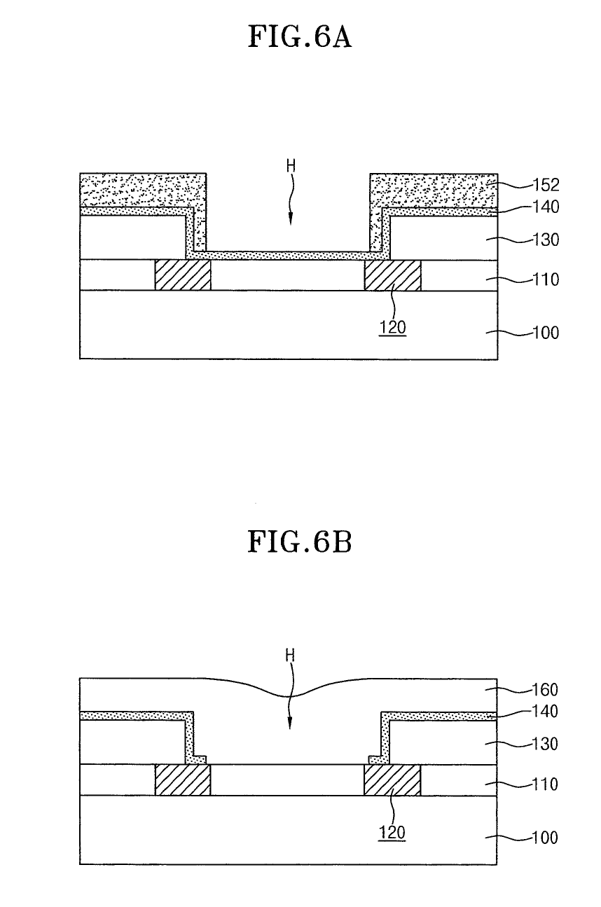

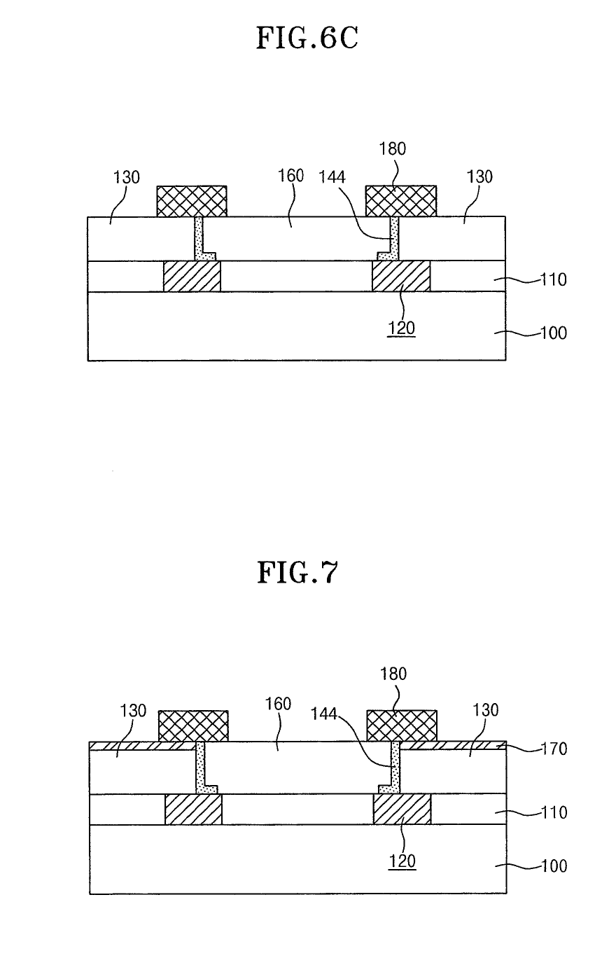

FIGS. 6A through 6C are cross-sectional views illustrating a phase change memory device in accordance with a third embodiment of the present invention and the processes for a method of manufacturing the same. Herein, the same reference numerals will be used to refer to the same parts as those shown in FIGS. 3A through 3F.

A phase change memory device in accordance with a third embodiment of the present invention has a configuration in which phase change layers 144 are formed to have an ‘L’ shape when viewed as a cross-section. Hereinbelow, a method of manufacturing the phase change memory device in accordance with the third embodiment of the present invention will be described.

Referring to FIG. 6A, a second insulation layer 130 comprising an oxide layer is formed on a first insulation layer 110 and first electrodes 120. A hole H is defined in two adjoining cells to expose portions of the first electrodes 120 and a portion of the first insulation layer 110 by etching the second insulation layer 130. The hole H is defined to expose a 5˜100 nm wide portion of each of the first electrodes 120. The hole H is also defined to have a rectangular shape or an oval shape when viewed from above.

A phase change material layer 140 is formed on portions of the first electrodes 120 and a portion of the first insulation layer 110, which are exposed through the hole H and on the sidewalls and upper surface of the etched second insulation layer 130. A photoresist pattern 152 is formed to expose a portion of the phase change material layer 140, which is formed on the first insulation layer 110. At this time, the photoresist pattern 152 is formed such that phase change layers can be subsequently formed to have an ‘L’ shape when viewed as a cross-section. That is, the width of the exposed portion of the phase change material layer 140 by the photoresist pattern 152 is less than that in the aforementioned embodiments.

Referring to FIG. 6B, the exposed portion of the phase change material layer 140 is etched using the photoresist pattern 152 as an etch mask. The photoresist pattern 152 is then removed. A third insulation layer 160 is formed on the remaining portion of the phase change material layer 140 and on the portion of the first insulation layer 110 and the portions of the first electrodes 120, which are exposed due to the etching of the phase change material layer 140. Third insulation layer 160 is formed such that the hole H is filled with the third insulation layer 160.

Referring to FIG. 6C, plug-shaped phase change layers 144 that contact the first electrodes 120 are formed by CMPing the third insulation layer 160 and the phase change material layer 140 until the second insulation layer 130 is exposed. The plug-shaped phase change layers 144 are formed to have an ‘L’ shape when viewed as a cross-section. Preferably, in two adjoining cells, the plug-shaped phase change layers 144 are formed to have an ‘L’ shape and a mirror-imaged ‘L’ shape facing one another when viewed as a cross-section. Also, the plug-shaped phase change layers 144 are formed to have the shape of a horseshoe or a semicircle when viewed from the above. Preferably, when viewed from the top, the plug-shaped phase change layers 144 of two adjoining cells have the shape of horseshoes which are opened inwardly towards one another or the shape of semicircles which are opened inwardly towards one another.

Next, bit lines 180 are formed on the second insulation layer 130 and the third insulation layer 160, including the plug-shaped phase change layers 144. The bit lines 180 are formed such that the bit lines 180 contact the phase change layers 144 and serve as second electrodes which correspond to the upper electrodes of capacitors.

In the phase change memory device according to the third embodiment of the present invention, the same effects as those of the aforementioned first embodiment are obtained, and therefore, detailed description thereof will be omitted herein.

FIG. 7 is a cross-sectional view illustrating a phase change memory device in accordance with a fourth embodiment of the present invention.

As shown in FIG. 7, a phase change memory device in accordance with a fourth embodiment of the present invention has a configuration in which plug-shaped phase change layers 144 have an ‘L’ shape, preferably, the shape of an ‘L’ and a mirror-imaged ‘L’ in two adjoining cells, when viewed as a cross-section. The plug-shaped phase change layers 144 also have a horseshoe or a semicircle shape, preferably, the shape of horseshoes which are opened inwardly towards one another or the shape of semicircles that are opened inwardly towards one another, in two adjoining cells, when viewed from the above. Further, the phase change memory device in accordance with the fourth embodiment of the present invention has a configuration in which a fourth insulation layer 170 (i.e. a nitride layer) is additionally formed on the second insulation layer 130 interposed between the second insulation layer 130 and bit lines 180.

The other component elements of the phase change memory device according to the fourth embodiment of the present invention are the same as those of the aforementioned embodiments, and therefore, detailed description thereof will be omitted herein.

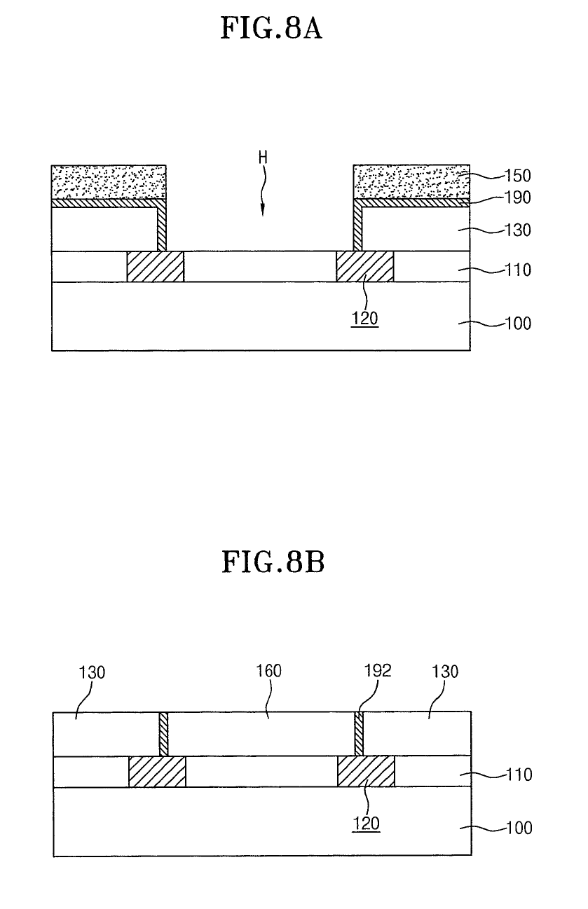

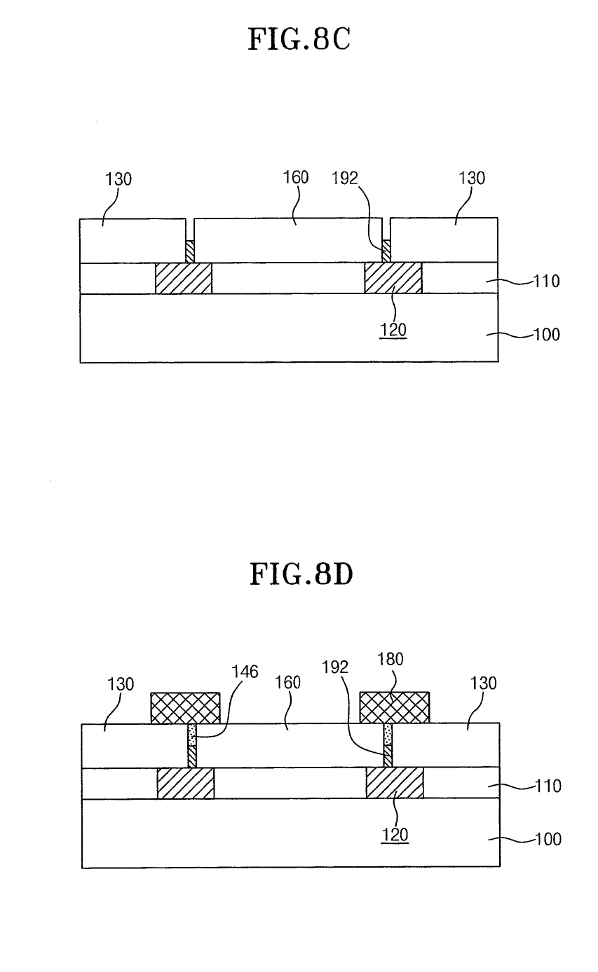

FIGS. 8A through 8D are cross-sectional views illustrating a phase change memory device in accordance with a fifth embodiment of the present invention and the processes for a method of manufacturing the same. Herein, the same reference numerals will be used to refer to the same parts as those shown in FIGS. 3A through 3F.

A phase change memory device in accordance with a fifth embodiment of the present invention has a configuration in which heaters 192 are interposed between first electrodes 120 and phase change layers 146 to ensure reliable occurrence of the phase change in the phase change layer 146. Hereinbelow, a method of manufacturing this phase change memory device will be described.

Referring to FIG. 8A, a first insulation layer 110 and first electrodes 120 are formed on a semiconductor substrate 100 having switching elements. A second insulation layer 130 (i.e. an oxide layer) is formed on the first insulation layer 110 and the first electrodes 120. A hole H is defined in two adjoining cells to expose portions of the first electrodes 120 and a portion of the first insulation layer 110 by etching the second insulation layer 130.

The hole H is defined to expose a 5˜100 nm wide portion of each of the first electrode 120 and to have a rectangular shape or an oval shape when viewed from above. A conductive layer 190 is formed on the portions of the first electrodes 120 and the portion of the first insulation layer 110, which are exposed through the hole H and on the sidewalls and upper surface of the etched second insulation layer 130. The conductive layer 190 is formed of any one of TiW, TiN and TiAlN to have a thickness of 5˜50 Å. A photoresist pattern 150 is formed on the conductive layer 190 such that a portion of the conductive layer 190, which is formed on the first insulation layer 110 is exposed.

Referring to FIG. 8B, the exposed portion of the conductive layer 190 is etched using the photoresist pattern 150 as an etch mask upon which the photoresist pattern 150 is subsequently removed. A third insulation layer 160 is formed on the remaining portion of the conductive layer 190 and the portion of the first insulation layer 110 and the portions of the first electrodes 120, which are exposed due to the etching of the conductive layer 190. The third insulation layer 160 is formed such that the hole H is filled with the third insulation layer 160. Plug-shaped heaters 192 are formed on both sidewalls of the hole H to contact the first electrodes 120 by CMPing the third insulation layer 160 and the conductive layer 190 until the second insulation layer 130 is exposed. The plug-shaped heaters 192 are formed to have a straight-line shape when viewed as a cross-section. The plug-shaped heaters 192 are also formed to have a horseshoe or a semicircle shape when viewed from above. Preferably, when viewed from the top, the plug-shaped heaters 192 of two adjoining cells have the shape of horseshoes which are opened inwardly towards one another or the shape of semicircles that are opened inwardly towards one another.

Referring to FIG. 8C, a portion of the heaters 192 is removed. Approximately 100˜2,000 Å of the heaters 192 is removed in relation to the surface of the second insulation layer 130 when the thickness of the second insulation layer 130 is 3,000˜4,000 Å.

Referring to FIG. 8D, plug-shaped phase change layers 146 are formed to contact the first electrodes 120 via the heaters 192 by filling a phase change material layer in the spaces remaining after the removal of the heaters 192. The plug-shaped phase change layers 146 are formed to have a straight-line shape when viewed as a cross-section and the shape of a horseshoe or a semicircle when viewed from above. Preferably, when viewed from the top, the plug-shaped phase change layers 146 of two adjoining cells have the shape of horseshoes which are opened inwardly towards one another or the shape of semicircles which are opened inwardly towards one another.

Bit lines 180 are formed on the second insulation layer 130 and the third insulation layer 160 including the plug-shaped phase change layers 146. Bit lines 180 are formed such that the bit lines 180 contact the phase change layers 146 and serve as second electrodes which correspond to the upper electrodes of capacitors.

In the phase change memory device according to the fifth embodiment of the present invention, the same effects as those of the aforementioned embodiments are obtained, and therefore, detailed description thereof will be omitted herein.

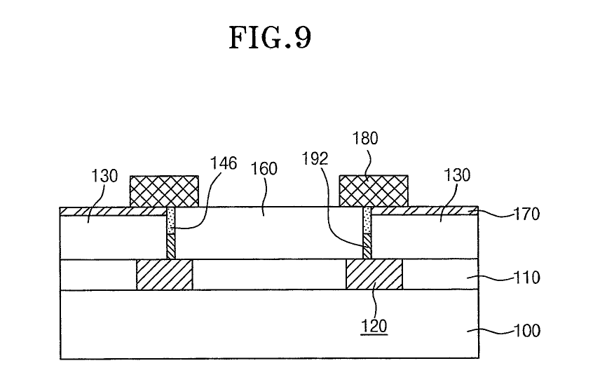

FIG. 9 is a cross-sectional view illustrating a phase change memory device in accordance with a sixth embodiment of the present invention.

Referring to FIG. 9, when compared to the phase change memory device in accordance with the fifth embodiment of the present invention, a phase change memory device in accordance with a sixth embodiment of the present invention has a configuration in which a fourth insulation layer 170 (i.e. a nitride layer) is additionally formed on the second insulation layer 130 interposed between the second insulation layer 130 and bit lines 180.

The other component elements of the phase change memory device according to the sixth embodiment of the present invention are the same as those of the fifth embodiment of the present invention described above, and therefore, detailed description thereof will be omitted herein.

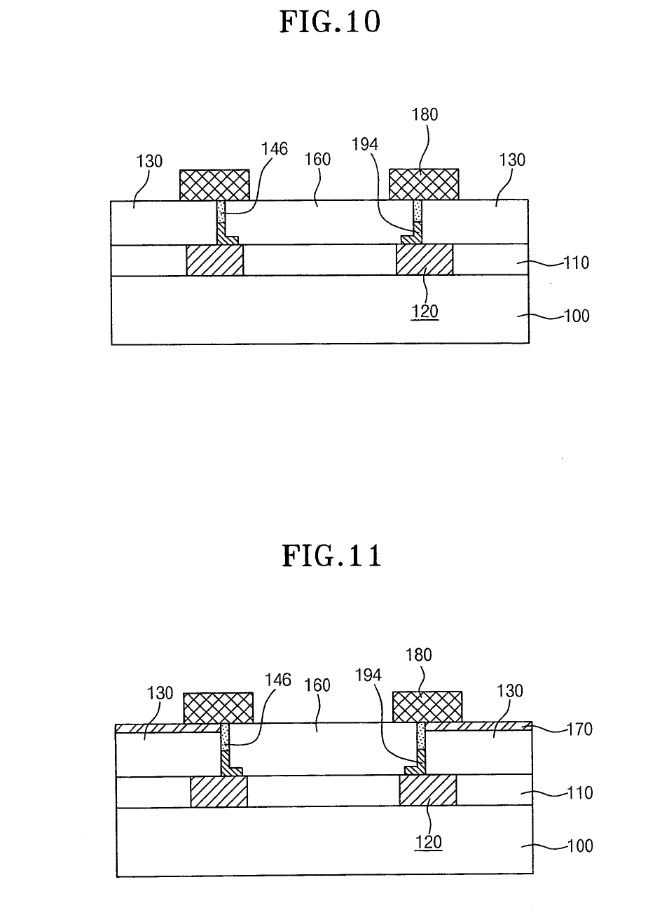

FIG. 10 is a cross-sectional view illustrating a phase change memory device in accordance with a seventh embodiment of the present invention.

As shown in FIG. 10, a phase change memory device in accordance with a seventh embodiment of the present invention has a configuration wherein heaters 194 are formed to have the shape of a horseshoe or a semicircle when viewed from above. Preferably, when viewed from above, the heaters 194 of two adjoining cells have the shape of horseshoes which are opened inwardly towards one another or the shape of semicircles which are opened inwardly towards one another. The heaters 194 are also formed to have an ‘L’ shape when viewed as a cross-section. Preferably, in two adjoining cells, the heaters 194 are formed to have an ‘L’ shape and a mirror-imaged ‘L’ shape when viewed as a cross-section.

The other component elements of the phase change memory device according to the seventh embodiment of the present invention are the same as those of the sixth embodiment of the present invention described above, and therefore, a detailed description thereof will be omitted herein.

FIG. 11 is a cross-sectional view illustrating a phase change memory device in accordance with an eighth embodiment of the present invention.

As shown in FIG. 11, a phase change memory device in accordance with an eighth embodiment of the present invention has a configuration wherein heaters 194 are formed to have an ‘L’ shape when viewed as a cross-section. Preferably, in two adjoining cells, the heaters 194 are formed to have an ‘L’ shape and a mirror-imaged ‘L’ shape when viewed as a cross-section. The heaters 194 are also formed to have the shape of a horseshoe or a semicircle when viewed from above. Preferably, when viewed from the top, the heaters 194 of two adjoining cells have the shape of horseshoes which are opened inwardly towards one another or the shape of semicircles which are opened inwardly towards one another. Further, the phase change memory device in accordance with the eighth embodiment of the present invention has a configuration in which a fourth insulation layer 170 (i.e. a nitride layer) is additionally formed on the second insulation layer 130 interposed between the second insulation layer 130 and bit lines 180.

The other component elements of the phase change memory device according to the eighth embodiment of the present invention are the same as those of the seventh embodiment of the present invention described above, and therefore, a detailed description thereof will be omitted herein.

As is apparent from the above description, in the embodiments of the present invention, it is possible to prevent the composition of a phase change material layer from being changed due to an etch loss on the periphery of the phase change material layer due to the fact that a phase change layer is formed in the shape of a plug. Also, in the present invention, it is not necessary to separately form a passivation layer to cover the periphery of the phase change layer. Therefore, it is possible to prevent voids from being generated since the phase change layer is formed in the shape of a plug.

Moreover, in the present invention, the size of a cell can be decreased and the distribution of programming current over the entire region of a semiconductor substrate can be standardized due to the fact that the phase change layer is formed in the shape of a plug. Further, in the present invention, it is possible to prevent a lifting phenomenon from occurring in the phase change material layer during a cleaning process since the phase change layer is formed in the shape of a plug. Accordingly, the characteristics of the interface between a lower electrode and the phase change layer can be improved. It is also possible to prevent the current required for the phase change of the phase change layer from increasing and the endurance of the phase change memory device from being degraded.

Furthermore, in the present invention, after defining a hole in two adjoining cells, phase change layers are formed on the sidewalls of the hole. It is therefore possible to overcome the limitations of a photolithographic process, and as a result, the contact area between the lower electrode and the phase change layer can decrease thereby decreasing the programming current. In addition, in the present invention, the programming current required for phase change can further be decreased due to the heat generated from a reduced height of the phase change layer because the phase change layer is formed in the shape of a plug. Also, in the present invention, a voltage drop due to resistance can be decreased since a bit line directly contacts the phase change layer formed in the shape of a plug and thereby, current flow can be promoted since a difference in voltage between the bit line and the lower electrode can be increased.

Although specific embodiments of the present invention have been described for illustrative purposes, those skilled in the art will appreciate that various modifications, additions and substitutions are possible, without departing from the scope and the spirit of the invention as disclosed in the accompanying claims.

What is claimed is:

1. A phase change memory device comprising:
first electrodes;
an insulation layer formed to cover the first electrodes;
plug-shaped phase change layers formed in the insulation layer to contact the first electrodes at a first end; and
bit lines formed on the insulation layer to contact the plug-shaped phase change layers at a second end, and
wherein the bit lines serve as second electrodes.

2. The phase change memory device according to claim 1, wherein the plug-shaped phase change layers have a vertical straight line shape when the phase change memory device is viewed as a lateral cross section parallel to the formation of the phase change memory device layers.

3. The phase change memory device according to claim 1, wherein the plug-shaped phase change layers have an ‘L’ shape when the phase change memory device is viewed as a lateral cross section parallel to the formation of the phase change memory device layers.

4. The phase change memory device according to claim 1, wherein the plug-shaped phase change layers have a horseshoe shape when the phase change memory device is viewed from above perpendicular to the formation of the plug-shaped phase change layers.

5. The phase change memory device according to claim 1, wherein the plug-shaped phase change layers have a semicircle shape when the phase change memory device is viewed from above perpendicular to the formation of the plug-shaped phase change layers.

6. The phase change memory device according to claim 1, further comprising:
heaters formed from a conductive layer interposed between the first electrodes and the plug-shaped phase change layers.

7. The phase change memory device according to claim 6, wherein the shape of both the heaters and the plug-shaped phase change layers have a vertical straight line shape when the phase change memory device is viewed as a lateral cross section parallel to the formation of the phase change memory device layers.

8. The phase change memory device according to claim 6, wherein the heaters have an ‘L’ shape and the plug-shaped phase change layers have a vertical straight line shape when the phase change memory device is viewed as a lateral cross section parallel to the formation of the phase change memory device layers.

9. A phase change memory device comprising:
a semiconductor substrate having switching elements;
a first insulation layer formed on the semiconductor substrate;
first electrodes formed in the first insulation layer;
plug-shaped phase change layers having an inner surface and an outer surface formed to contact the first electrodes at a first end;
a second insulation layer formed on a first portion of the first electrodes and a first portion of the first insulation layer that is adjacent to the first portion of the first electrodes to contact the outer surface of the phase change layers;
a third insulation layer formed on a second portion of the first electrodes and a second portion of the first insulation layer that is adjacent to the second portion of the first electrodes to contact the inner surface of the phase change layers; and
bit lines formed on the second insulation layer and the third insulation layer to contact the phase change layers at a second end, and
wherein the bit lines serve as second electrodes.

10. The phase change memory device according to claim 9, wherein each of the first insulation layer, the second insulation layer and the third insulation layer comprises an oxide layer.

11. The phase change memory device according to claim 9, further comprising:
a fourth insulation layer formed on the second insulation layer interposed between the second insulation layer and the bit lines.

12. The phase change memory device according to claim 11, wherein the fourth insulation layer comprises a nitride layer.

13. The phase change memory device according to claim 9, wherein the plug-shaped phase change layers have a vertical straight line shape when the phase change memory device is viewed as a lateral cross section parallel to the formation of the phase change memory device layers.

14. The phase change memory device according to claim 9, wherein the plug-shaped phase change layers have an ‘L’ shape when the phase change memory device is viewed as a lateral cross section parallel to the formation of the phase change memory device layers.

15. The phase change memory device according to claim 14, wherein, in two adjoining cells, the plug-shaped phase change layers have an ‘L’ shape and a mirror-imaged ‘L’ shape when the phase change memory device is viewed as a lateral cross section parallel to the formation of the phase change memory device layers.

16. The phase change memory device according to claim 9, wherein the plug-shaped phase change layers have a horseshoe shape when the phase change memory device is viewed from above perpendicular to the formation of the plug-shaped phase change layers.

17. The phase change memory device according to claim 16, wherein, in two adjoining cells, the plug-shaped phase change layers having the horseshoe shape are formed to open inwardly towards one another when the phase change memory device is viewed from above perpendicular to the formation of the plug-shaped phase change layers.

18. The phase change memory device according to claim 9, wherein the plug-shaped phase change layers have a semicircle shape when the phase change memory device is viewed from above perpendicular to the formation of the plug-shaped phase change layers.

19. The phase change memory device according to claim 18, wherein, in two adjoining cells, the plug-shaped phase change layers having the semicircle shape are formed to open inwardly towards one another when the phase change memory device is viewed from above perpendicular to the formation of the plug-shaped phase change layers.

20. The phase change memory device according to claim 9, further comprising:
heaters formed from a conductive layer interposed between the first electrodes and the plug-shaped phase change layers.

21. The phase change memory device according to claim 20, wherein the shape of both the heaters and the plug-shaped phase change layers have a vertical straight line shape when the phase change memory device is viewed as a lateral cross section parallel to the formation of the phase change memory device layers.

22. The phase change memory device according to claim 20, wherein the heaters have an ‘L’ shape and the plug-shaped phase change layers have a vertical straight line shape when the phase change memory device is viewed as a lateral cross section parallel to the formation of the phase change memory device.

23. A method for manufacturing a phase change memory device, comprising the steps of:
forming a first insulation layer on a semiconductor substrate having switching elements;
forming first electrodes in the first insulation layer;
forming a second insulation layer on the first insulation layer to cover the first electrodes;
etching the second insulation layer of two adjoining cells and thereby defining a hole to expose portions of the first electrodes and a portion of the first insulation layer located between the exposed portions of the first electrodes;
forming a phase change material layer on the exposed portions of the first electrodes and the first insulation layer and on sidewalls and an upper surface of the second insulation layer that has been etched;
removing a portion of the phase change material layer that is formed on the first insulation layer;
forming a third insulation layer on the phase change material layer to fill the hole;
removing a portion of the third insulation layer and a portion of the phase change material layer to expose the second insulation layer and thereby forming plug-shaped phase change layers on both sidewalls of the hole; and
forming bit lines on the second insulation layer and the third insulation layer to contact the phase change layers and to serve as second electrodes.

24. The method according to claim 23, wherein each of the first insulation layer, the second insulation layer and the third insulation layer is formed as an oxide layer.

25. The method according to claim 23, wherein the hole is defined to have a rectangular shape when the phase change memory device is viewed from above perpendicular to the formation of the plug-shaped phase change layers.

26. The method according to claim 23, wherein the hole is defined to have an oval shape when the phase change memory device is viewed from above perpendicular to the formation of the plug-shaped phase change layers.

27. The method according to claim 23, wherein the hole is defined to expose a portion of each of the first electrode 5˜100 nm in width.

28. The method according to claim 23, wherein the plug-shaped phase change layers are formed to have a vertical straight line shape when the phase change memory device is viewed as a lateral cross section parallel to the formation of the phase change memory device layers.

29. The method according to claim 23, wherein the plug-shaped phase change layers are formed to have an ‘L’ shape when the phase change memory device is viewed as a lateral cross section parallel to the formation of the phase change memory device layers.

30. The method according to claim 29, wherein, in two adjoining cells, the plug-shaped phase change layers are formed to have an ‘L’ shape and a mirror-imaged ‘L’ shape when the phase change memory device is viewed as a lateral cross section parallel to the formation of the phase change memory device layers.

31. The method according to claim 23, wherein the plug-shaped phase change layers are formed to have a horseshoe shape when the phase change memory device is viewed from above perpendicular to the formation of the plug-shaped phase change layers.

32. The method according to claim 31, wherein, in two adjoining cells, the plug-shaped phase change layers formed to have the horseshoe shape open inwardly towards one another when the phase change memory device is viewed from above perpendicular to the formation of the plug-shaped phase change layers.

33. The method according to claim 23, wherein the plug-shaped phase change layers are formed to have a semicircle shape when the phase change memory device is viewed from above perpendicular to the formation of the plug-shaped phase change layers.

34. The method according to claim 33, wherein, in two adjoining cells, the plug-shaped phase change layers formed to have the semicircle shape open inwardly towards one another when the phase change memory device is viewed from above perpendicular to the formation of the plug-shaped phase change layers.

35. A method for manufacturing a phase change memory device, comprising the steps of:
forming a first insulation layer on a semiconductor substrate having switching elements;
forming first electrodes in the first insulation layer;
forming a second insulation layer on the first insulation layer to cover the first electrodes;
etching the second insulation layer of two adjoining cells and thereby defining a hole to expose portions of the first electrodes and a portion of the first insulation layer located between the exposed portions of the first electrodes;
forming a conductive layer on the exposed portions of the first electrodes and the first insulation layer, and on sidewalls and an upper surface of the second insulation layer that has been etched;
removing a portion of the conductive layer that is formed on the first insulation layer;
forming a third insulation layer on the conductive layer to fill the hole;
removing a portion of the third insulation layer and a portion of the conductive layer to expose the second insulation layer and thereby forming heaters on both sidewalls of the hole;
removing a portion of each of the heaters thereby forming a space;
filling a phase change material layer in the spaces defined by the removal of the portions of the heaters to form plug-shaped phase change layers; and
forming bit lines on the second insulation layer and the third insulation layer to contact the phase change layers and to serve as second electrodes.

36. The method according to claim 35, wherein each of the first insulation layer, the second insulation layer and the third insulation layer is formed as an oxide layer.

37. The method according to claim 35, wherein the hole is defined to have a rectangular shape when the phase change memory device is viewed from above perpendicular to the formation of the plug-shaped phase change layers.

38. The method according to claim 35, wherein the hole is defined to have an oval shape when the phase change memory device is viewed from above perpendicular to the formation of the plug-shape phase change layers.

39. The method according to claim 35, wherein the hole is defined to expose a portion of each of the first electrode 5˜100 nm in width.

40. The method according to claim 35, wherein the conductive layer is formed of any one selected form the group consisting of TiW, TiN and TIAlN.

41. The method according to claim 35, wherein the conductive layer is formed to have a thickness of 5˜50 Å.

42. The method according to claim 35, wherein the heaters are formed to have a vertical straight line shape when the phase change memory device is viewed as a lateral cross section parallel to the formation of the phase change memory device layers.

43. The method according to claim 35, wherein the heaters are formed to have an ‘L’ shape when the phase change memory device is viewed as a lateral cross section parallel to the formation of the phase change memory device layers.

44. The method according to claim 43, wherein, in two adjoining cells, the heaters are formed to have an ‘L’ shape and a mirror-imaged ‘L’ shape when the phase change memory device is viewed as a lateral cross section parallel to formation of the phase change memory device layers.

45. The method according to claim 35, wherein the heaters are formed to have a horseshoe shape when the phase change memory device is viewed from above perpendicular to the formation of the plug-shaped phase change layers.

46. The method according to claim 35, wherein the heaters are formed to have a semicircle shape when the phase change memory device is viewed from above perpendicular to the formation of the plug-shaped phase change layers.

47. The method according to claim 35, wherein the step of removing a portion of each of the heaters comprises removing a portion of the heater to a depth of 100˜2,000 Å below a surface of the second insulation layer.

48. The method according to claim 35, wherein the plug-shaped phase change layers are formed to have a vertical straight line shape when the phase change memory device is viewed as a lateral cross section parallel to the formation of the phase change memory device layers.

49. The method according to claim 35, wherein the plug-shaped phase change layers are formed to have a horseshoe shape when the phase change memory device is viewed from above perpendicular to the formation of the plug-shaped phase change layers.

50. The method according to claim 35, wherein the plug-shaped phase change layers are formed to have a semicircle shape when the phase change memory device is viewed from above perpendicular to the formation of the plug-shaped phase change layers.
